(19) United States
(12) Patent Application Publication
(10) Pub. No.: US 2025/0045481 A1
(43) Pub. Date: Feb. 6, 2025

(54) INFORMATION GENERATING DEVICE, INFORMATION GENERATING SYSTEM, INFORMATION GENERATING METHOD, AND STORAGE MEDIUM STORING INFORMATION GENERATING PROGRAM

(71) Applicant: NIPPON TELEGRAPH AND TELEPHONE CORPORATION, Tokyo (JP)

(72) Inventors: Atsuhiko MAEDA, Tokyo (JP); Kazuaki OBANA, Tokyo (JP); Yukio KIKUYA, Tokyo (JP); Kenichi FUKUDA, Tokyo (JP)

(73) Assignee: NIPPON TELEGRAPH AND TELEPHONE CORPORATION, Tokyo (JP)

(21) Appl. No.: 18/580,127

(22) PCT Filed: Jul. 21, 2021
(86) PCT No.: PCT/JP2021/027399

§ 371 Date: Jan. 17, 2024

(51) Int. Cl. G06F 30/20

(52) U.S. Cl. CPC G06F 30/20

(57) ABSTRACT

An information generation device acquires past event information including information on a position where a predetermined event occurred and supplementary information regarding the position, and generates simulated event information obtained by simulating occurrence of the event in a predetermined area, with an occurrence position of the simulated event information being a position in the predetermined area based on the position included in the past event information and the supplementary information regarding the position.

### TECHNICAL FIELD

The disclosed technology relates to an information generation device, an information generation system, an information generation method, and an information generation program.

### BACKGROUND ART

There is a technology in which an occurrence probability of a predetermined event is calculated for each set of latitude and longitude, a two-dimensional distribution of occurrence probabilities of the event is estimated, a plurality of simulated occurrence patterns of the event is created from the estimated two-dimensional distribution of occurrence probabilities, and the simulated occurrence patterns are used for simulation.

As a technology for estimating a two-dimensional distribution of occurrence probabilities of an event as described above, a technology using kernel density estimation has been proposed. For example, Non Patent Literature 1 discloses a technology of constructing a spatial database of piracy incidents that have occurred in the waters off Somalia to be analyzed and then performing spatial interpolation using a kernel density estimation method to grasp a geographical distribution characteristic of points where pirates appeared in order to visualize hot spots for piracy in the waters off Somalia.

### CITATION LIST

### Non Patent Literature

Non Patent Literature 1: Yasuhiro Nagata, Daisuke Watanabe, and Shigeki Toriumi, “Spatial Analysis Using Kernel Density Estimation on Somali Pirates”, Papers and proceedings of the Geographic Information Systems Association (CD-ROM), 2013

### SUMMARY OF INVENTION

### Technical Problem

In a case of creating simulated occurrence patterns of an event as described above, it is conceivable to apply kernel density estimation as described in Non Patent Literature 1 when estimating a two-dimensional distribution of occurrence probabilities of the event. In this case, in general, the kernel density estimation is performed on a data sequence of occurrence positions of events in the past in an applied condition, a density is computed for each set of coordinates, and the two-dimensional distribution of occurrence probabilities of the event is estimated. Then, in accordance with the estimated two-dimensional distribution, simulated occurrence patterns of the event are created. In this case, there is a problem in that it takes time to calculate the kernel density estimation.

Furthermore, in the kernel density estimation, for example, when occurrence probabilities between past event occurrence points are obtained, interpolation processing is often performed by applying a single interpolation method such as Gaussian distribution. However, in a case where the occurrence probabilities between the event occurrence points are uniformly interpolated with Gaussian distribution, actualities are not appropriately reflected, and an inaccurate two-dimensional distribution of occurrence probabilities may be estimated.

The disclosed technology has been made in view of the above points, and an object thereof is to provide an information generation device, an information generation system, an information generation method, and an information generation program capable of creating simulated event information obtained by simulating occurrence of a predetermined event at a higher speed, while enhancing reflection of actual occurrence of the event.

### Solution to Problem

A first aspect of the present disclosure provides an information generation device including: an acquisition unit that acquires past event information including information on a position where a predetermined event occurred and supplementary information regarding the position; and a generation unit that generates simulated event information obtained by simulating occurrence of the event in a predetermined area, with an occurrence position of the simulated event information being a position in the predetermined area based on the position included in the past event information and the supplementary information regarding the position.

A second aspect of the present disclosure provides an information generation system including: an acquisition unit that acquires past event information including information on a position where a predetermined event occurred and supplementary information regarding the position; and a generation unit that generates simulated event information obtained by simulating occurrence of the event in a predetermined area, with an occurrence position of the simulated event information being a position in the predetermined area based on the position included in the past event information and the supplementary information regarding the position.

A third aspect of the present disclosure provides an information generation method including: acquiring, by an acquisition unit, past event information including information on a position where a predetermined event occurred and supplementary information regarding the position; and generating, by a generation unit, simulated event information obtained by simulating occurrence of the event in a predetermined area, with an occurrence position of the simulated event information being a position in the predetermined area based on the position included in the past event information and the supplementary information regarding the position.

A fourth aspect of the present disclosure is an information generation program for causing a computer to function as each unit of the information generation device of the first aspect.

### Advantageous Effects of Invention

According to the disclosed technology, it is possible to create simulated event information obtained by simulating occurrence of a predetermined event at a higher speed, while enhancing reflection of actual occurrence of the event.

### BRIEF DESCRIPTION OF DRAWINGS

FIG. 1 is a schematic diagram illustrating an example of a hardware configuration of an information generation system according to an embodiment.

FIG. 2 is a block diagram illustrating an example of a functional configuration of an information generation device according to the embodiment.

FIG. 3 is a schematic diagram illustrating an example of a configuration of an event database according to the embodiment.

FIG. 4 is a schematic diagram illustrating an example of an area including a predetermined area according to the embodiment.

FIG. 5 is a schematic diagram illustrating an example of a case of computing a distribution bias in an occurrence probability of injury or disease by kernel density estimation.

FIG. 6 is a schematic diagram illustrating an example of a case of selecting a selected position according to the embodiment.

FIG. 7 is a schematic diagram illustrating an example of a case of generating simulated event information in accordance with the type of a facility related to a selected position according to the embodiment.

FIG. 8 is a flowchart illustrating an example of information generation processing in the information generation device according to the embodiment.

### DESCRIPTION OF EMBODIMENTS

Hereinafter, an example of an embodiment of the disclosed technology will be described with reference to the drawings. In the drawings, the same or equivalent components and parts will be denoted by the same reference signs. Dimensional ratios in the drawings are exaggerated for convenience of description, and may be different from actual ratios.

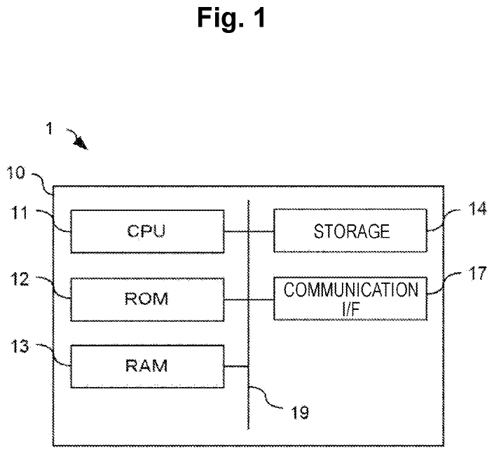

As illustrated in FIG. 1, an information generation system 1 has an information generation device 10. The information generation device 10 has a central processing unit (CPU) 11, a read only memory (ROM) 12, a random access memory (RAM) 13, a storage 14, and a communication interface (I/F) 17. The components are communicatively connected to each other via a bus 19.

The CPU 11 is a central processing unit, and executes various programs and controls each unit. That is, the CPU 11 reads a program from the ROM 12 or the storage 14 and executes the program by using the RAM 13 as a work area. The CPU 11 controls each of the components described above and performs various types of arithmetic processing in accordance with the program stored in the ROM 12 or the storage 14. In the present embodiment, an information generation program is stored in the ROM 12 or the storage 14. The information generation program may be one program or a program group including a plurality of programs or modules.

The ROM 12 stores various programs and various types of data. The RAM 13, as a work area, temporarily stores programs or data. The storage 14 includes a hard disk drive (HDD) or a solid state drive (SSD) and stores various programs including an operating system and various types of data.

The communication I/F 17 is an interface for communicating with another device, and for example, standards such as Ethernet (registered trademark), FDDI, and Wi-Fi (registered trademark) are used.

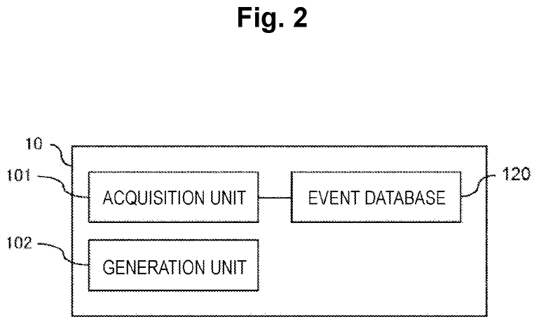

Next, a functional configuration of the information generation device 10 will be described. As illustrated in FIG. 2, the information generation device 10 includes an acquisition unit 101 and a generation unit 102. The information generation device 10 further includes an event database 120.

The acquisition unit 101 acquires, from the event database 120, past event information including information on a position where a predetermined event occurred in a predetermined area, and supplementary information regarding the position. Alternatively, the acquisition unit 101 may acquire past event information including information on a position where a predetermined event occurred in a predetermined area in a predetermined time zone, and supplementary information regarding the position. In the present embodiment, the latitude and longitude of the position where injury or disease occurred and the date and time when the injury or disease occurred are applied as the event information. In addition, in the present embodiment, the type of a facility in which injury or disease occurred is applied as the supplementary information. Hereinafter, the event information and the supplementary information are also referred to as “occurrence information”.

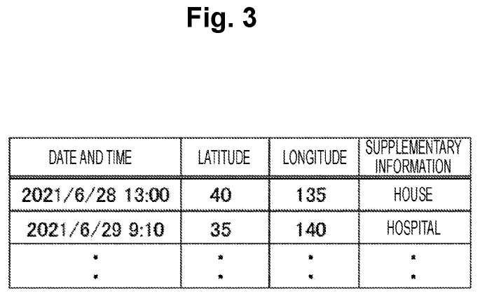

As illustrated in FIG. 3, the event database 120 is a database in which the latitude and longitude of the position where injury or disease occurred and the supplementary information are stored for each date and time when the injury or disease occurred. In FIG. 3, each row represents a piece of occurrence information. The event database 120 illustrated in FIG. 3 stores, as the supplementary information, information indicating whether the type of the facility in which injury or disease occurred is a first type or a second type, in which the second type is lower than the first type in probability that injury or disease may occur in a similar manner also in the vicinity of the position where the injury or disease occurred. In the present embodiment, a house is applied as the first type, and a hospital is applied as the second type. However, the present invention is not limited to these examples. For example, a building may be applied as the first type, and a school or the like may be applied as the second type. Alternatively, the types of facilities are not limited to two types, and three or more types may be set.

In addition, the acquisition unit 101 acquires an occurrence probability of injury or disease that falls into a specific condition in a predetermined area on the basis of the event information stored in the event database 120. Specifically, the acquisition unit 101 acquires, from the event database 120, the number of injuries and diseases that fall into a specific condition among injuries and diseases in a predetermined area during a predetermined period. For example, the specific condition is that the occurrence date and time is included in a specific time zone. In this case, the acquisition unit 101 counts the number of pieces of event information of which the date and time is included in the specific time zone and positions represented by latitude and longitude are included in the predetermined area, among pieces of event information during the predetermined period stored in the event database 120. Note that the specific condition is not limited to the above example, and the occurrence date and time may be a specific day of the week, for example. Then, the acquisition unit 101 acquires the occurrence probability of injury or disease by dividing the number of occurrences of injury or disease by the predetermined period. For example, a case is assumed in which the event database 120 includes 10 pieces of event information that fall into the following: the predetermined period is the last 100 days, the predetermined area is a specific region represented by a rectangular area, and the specific time zone is within the hour of 9 o'clock. In this case, the occurrence probability of injury or disease in the specific region within the hour of 9 o'clock is 0.1.

The acquisition unit 101 passes, to the generation unit 102, occurrence information in the predetermined area and the occurrence probability of injury or disease acquired from the event database 120.

The generation unit 102 generates simulated event information obtained by simulating occurrence of injury or disease in the predetermined area, with the occurrence position being a position in the predetermined area based on the occurrence information in the predetermined area acquired by the acquisition unit 101.

Specifically, in order to determine the number of pieces of simulated event information to be generated, the generation unit 102 uses the occurrence probability of injury or disease acquired by the acquisition unit 101 to construct an occurrence prediction model for injury or disease on the assumption that a probability distribution of the number of occurrences of injury or disease follows, for example, Poisson distribution. The generation unit 102 uses the occurrence prediction model to generate, in a simulated manner, the number of occurrences of injury or disease that fall into a specific condition in the predetermined area. It is assumed that a plurality of cases of occurrence of injury or disease within the hour of 9 o'clock in the specific region is simulated with an occurrence prediction model constructed on the basis of the occurrence probability of injury or disease within the hour of 9 o'clock in the specific region, the occurrence probability being 0.1. In this case, while the number of occurrences of injury or disease is zero in many cases, one occurrence is simulated in rare cases, and two occurrences are simulated in more rare cases.

In order to determine the occurrence position of each piece of simulated event information to be generated, the generation unit 102 randomly selects one piece of occurrence information from pieces of occurrence information in the predetermined area acquired by the acquisition unit 101. Hereinafter, the occurrence information selected by the generation unit 102 is referred to as selected information. Then, in a case where the type of the facility indicated by the supplementary information in the selected information is a house, the generation unit 102 generates simulated event information in which the occurrence position is a position obtained by adding noise to a position corresponding to the selected information (the position is hereinafter referred to as a “selected position”). Specifically, the generation unit 102 generates simulated event information in which the occurrence position is a position represented by latitude and longitude obtained by adding a predetermined value to at least one of latitude or longitude of the selected position. More specifically, the generation unit 102 adds, to at least one of the latitude or longitude of the selected position, a value generated using a random number in a range of numerical values corresponding to values in a certain range (e.g., −200 m to +200 m) in latitude and longitude. In a case where the type of the facility indicated by the supplementary information in the selected information is a house, there is a high possibility that the occurrence position is a residential area, and injuries and diseases may occur not only at the past occurrence position but also at other houses in that residential area. That is, there is a high possibility that injuries and diseases occur in a similar manner also in the vicinity of the selected position. With this processing, at a stage where the generation unit 102 selects the selected information, there is a high possibility that the information is selected from pieces of occurrence information of positions where the number of injuries and diseases is large, and furthermore, processing of shifting the occurrence position with respect to the selected position is performed, so that it is possible to appropriately simulate a simulated occurrence of injury or disease in another house.

On the other hand, in a case where the type of the facility indicated by the supplementary information in the selected information is a hospital, the generation unit 102 generates simulated event information in which the occurrence position is the selected position. In a case where the type of the facility indicated by the supplementary information in the selected information is a hospital, injuries and diseases are not likely to occur also in facilities in the vicinity of the hospital other than that hospital. That is, there is a low possibility that injury or disease occurs in the vicinity of the selected position. With this processing, it is possible to more accurately simulate occurrence of injury or disease in the hospital. In particular, the number of injuries and diseases that occur in hospitals account for a large percentage of the total number of occurrences of injury or disease. It is therefore possible to more accurately simulate occurrence of injury or disease in a hospital by storing, in the event database 120, supplementary information indicating the facility in which injury or disease occurred for making distinction between hospitals and the others as described above.

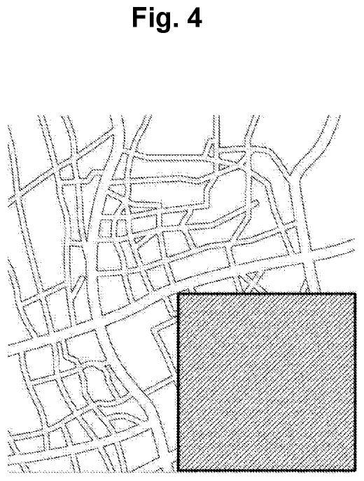

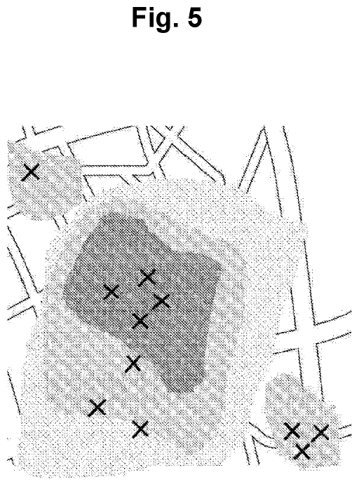

Here, in a case where the occurrence probability is uniformly distributed in a predetermined area, it is only required that occurrence positions of the simulated event information be randomly generated in the predetermined area, for example. However, in practice, it is unlikely that the occurrence probability is uniformly distributed in a predetermined area, and the occurrence probability is biased depending on the position in the predetermined area. For comparison, a case of computing a bias in occurrence probability of an event depending on the position by kernel density estimation will be described with reference to FIGS. 4 and 5. FIG. 4 is a map illustrating an area including a predetermined area (shaded area in the example illustrated in FIG. 4) for which occurrence of injury or disease is to be simulated. In a case of performing kernel density estimation, as illustrated in FIG. 5, the kernel density estimation is performed on the basis of positions (in the example illustrated in FIG. 5, positions indicated by cross marks) where injury or disease occurred in the past in the predetermined area illustrated in FIG. 4, and a distribution bias in the occurrence probability of injury or disease in the predetermined area is computed. When the distribution bias in the occurrence probability is computed, interpolation processing is performed by applying a single interpolation method such as Gaussian distribution, and the occurrence probability between the positions where injury or disease occurred in the past is calculated. In the example in FIG. 5, the occurrence probability at each position in the predetermined area is represented by the density of shading, and the higher the density of shading, the higher the occurrence probability. In the case of performing kernel density estimation, there is a problem in that it takes more time as the number of positions where injury or disease occurred in the past or the resolution of the two-dimensional plane increases. Furthermore, in a case where interpolation processing is performed by applying a single interpolation method, there is a possibility that actualities are not reflected in the positional bias in the occurrence probability. Thus, there is a problem in that the simulated event information generated using the occurrence probability may become inaccurate due to the actualities not being reflected.

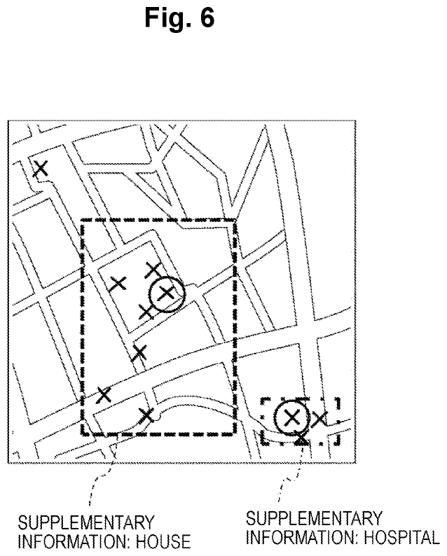

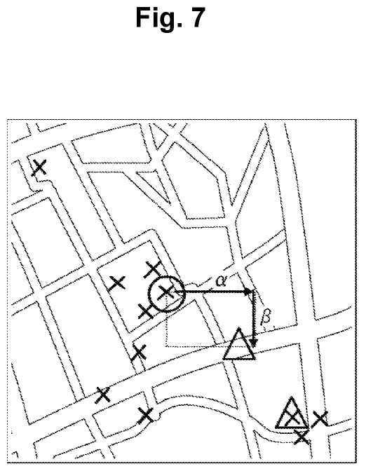

Next, a case of generating simulated event information in the present embodiment will be described with reference to FIGS. 4, 6, and 7. In the present embodiment, as illustrated in FIG. 6, first, a selected position (in the example illustrated in FIG. 6, the position indicated by a cross mark surrounded by a circle) is selected from positions where injury or disease occurred in the past (in the example illustrated in FIG. 6, the positions indicated by cross marks) in the predetermined area illustrated in FIG. 4. Then, as illustrated in FIG. 7, in a case where the type of the facility at the selected position is a house, simulated event information of a position (in the example illustrated in FIG. 7, the position indicated by a triangle mark) obtained by adding noise to the selected position is generated. In the example in FIG. 7, a is added in the longitude direction and B is added in the latitude direction as the noise. On the other hand, in a case where the type of the facility at the selected position is a hospital, simulated event information with the selected position as the occurrence position (in the example illustrated in FIG. 7, the position indicated by a cross mark surrounded by a triangle) is generated. With this processing, it is possible to generate simulated event information in which the positional bias in the occurrence probability of injury or disease in the predetermined area is accurately grasped.

Next, actions of the information generation device 10 will be described.

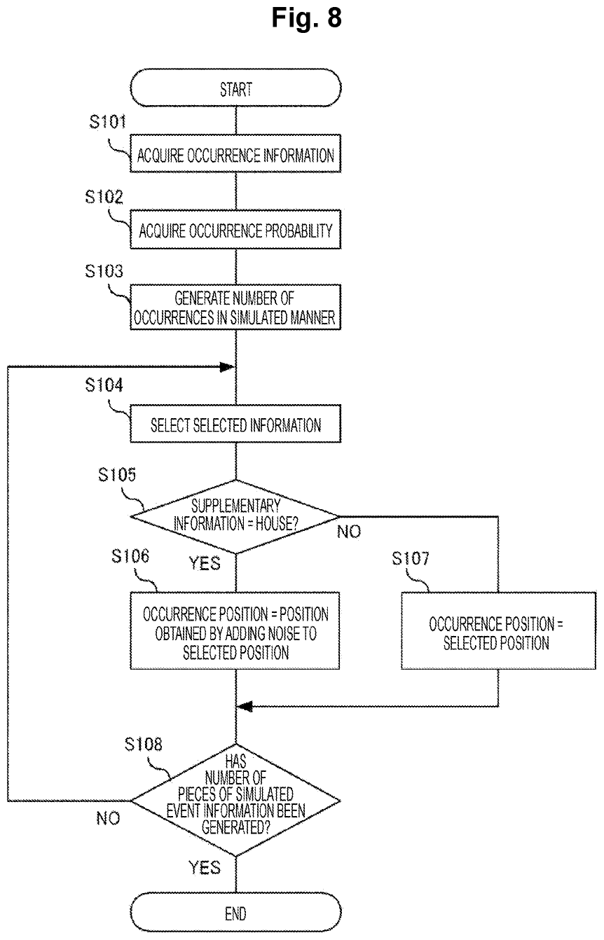

FIG. 8 is a flowchart illustrating a flow of processing by the information generation device 10. The CPU 11 reads the information generation program from the ROM 12 or the storage 14, develops the information generation program in the RAM 13, and executes the information generation program so that information generation processing is performed.

In step S101, the CPU 11, as the acquisition unit 101, acquires occurrence information in a predetermined area from the event database 120.

In step S102, the CPU 11, as the acquisition unit 101, acquires an occurrence probability of injury or disease that falls into a specific condition in the predetermined area by dividing the number of injuries and diseases that fall into the specific condition among injuries and diseases that occurred in the predetermined area during a predetermined period by the predetermined period.

In step S103, the CPU 11, as the generation unit 102, uses the occurrence probability of injury or disease acquired in step S102 to construct an occurrence prediction model of injury or disease, and uses the occurrence prediction model to generate, in a simulated manner, the number of occurrences of injury or disease that fall into the specific condition in the predetermined area.

In step S104, the CPU 11, as the generation unit 102, randomly selects one piece of selected information from pieces of the occurrence information acquired in step S101.

In step S105, the CPU 11, as the generation unit 102, determines whether the type of the facility indicated by supplementary information in the selected information selected in step S104 is a house. In a case where the type of the facility indicated by the supplementary information is a house (step S105: YES), the processing proceeds to step S106. On the other hand, in a case where the type of the facility indicated by the supplementary information is a hospital (step S105: NO), the CPU 11 proceeds to step S107.

In step S106, the CPU 11, as the generation unit 102, generates simulated event information in which the occurrence position is a position represented by latitude and longitude obtained by adding a predetermined value to at least one of latitude or longitude of a selected position.

In step S107, the CPU 11, as the generation unit 102, generates simulated event information in which the occurrence position is the selected position.

In step S108, the CPU 11, as the generation unit 102, determines whether the same number of pieces of simulated event information as the number of occurrences of injury or disease generated in a simulated manner in the processing in step S103 have been generated. In a case where the same number of pieces of simulated event information as the number of occurrences of injury or disease generated in a simulated manner have been generated (step S108: YES), the CPU 11 ends the present information generation processing. On the other hand, in a case where the same number of pieces of simulated event information as the number of occurrences of injury or disease generated in a simulated manner have not been generated (step S108: NO), the CPU 11 returns to step S104.

As described above, the information generation device according to the present embodiment acquires past event information including information on a position where a predetermined event occurred and supplementary information regarding the position. The information generation device generates simulated event information obtained by simulating occurrence of an event in a predetermined area, with the occurrence position being a position in the predetermined area based on the position included in the past event information and the supplementary information regarding the position. As a result, it is possible to create simulated event information obtained by simulating occurrence of a predetermined event at a higher speed, while enhancing reflection of actual occurrence of the event. Specifically, it is possible to more correctly grasp the probability distribution of occurrence positions as compared with a case where kernel density estimation is homogeneously performed with Gaussian distribution or the like. In addition, a case where the occurrence probability is calculated from, for example, 10 pieces of event information has been described in the present embodiment, but in practice, the number of pieces of past event information used for estimation of the occurrence probability is enormous in most cases, and as the number of pieces of past event information increases, the speed is increased more effectively.

### Modifications

Note that the present invention is not limited to the above-described embodiment, and various modifications and applications can be made without departing from the gist of the present invention.

For example, in the above embodiment, a case of generating simulated event information obtained by simulating occurrence of injury or disease has been described. However, the present invention is not limited to this example. For example, the present invention may be applied to a case of generating simulated event information obtained by simulating occurrence of a crime, a traffic jam, or the like.

Furthermore, in the above embodiment, a case of applying, as an example of event information, latitude and longitude of the position where injury or disease occurred and the date and time when the injury or disease occurred has been described, but another type of event information may be used. For example, the address of the position where injury or disease occurred and the date and time when the injury or disease occurred may be applied as event information. In this case, for example, in a case where the type of the facility indicated by the supplementary information in the selected information is a house, the generation unit 102 may generate simulated event information in which the occurrence position is a position represented by an address with the same zip code as the zip code of the selected position.

Furthermore, in the above embodiment, a case where the type of the facility in which the injury or disease occurred is applied as an example of supplementary information has been described, but another type of supplementary information may be used. For example, information regarding an event held at the position where the injury or disease occurred or the like may be used as supplementary information.

Various types of processing executed by the CPU reading and executing software (program) in the above embodiment may be executed by various processors other than the CPU. Examples of the processors in this case include a programmable logic device (PLD) of which a circuit configuration can be changed after manufacturing, such as a field-programmable gate array (FPGA), and a dedicated electric circuit that is a processor having a circuit configuration exclusively designed for executing specific processing, such as an application specific integrated circuit (ASIC). The information generation processing may be executed by one of these various processors or may be executed by a combination of two or more processors of the same type or different types (e.g., a plurality of FPGAS, or a combination of a CPU and an FPGA). More specifically, a hardware structure of the various processors is an electric circuit in which circuit elements such as semiconductor elements are combined.

In the above embodiment, an aspect in which the information generation program is stored (installed) in advance in the storage 14 has been described, but the present invention is not limited thereto. The program may be provided in the form of a program stored in a non-transitory storage medium such as a compact disk read only memory (CD-ROM), a digital versatile disk read only memory (DVD-ROM), or a universal serial bus (USB) memory. The program may be downloaded from an external device via a network.

Regarding the foregoing embodiment, the following supplementary notes are further disclosed.

### Supplementary Note 1

An information generation device including:
a memory; and
at least one processor connected to the memory,
in which the processor is configured to:
acquire past event information including information on a position where a predetermined event occurred and supplementary information regarding the position; and
generate simulated event information obtained by simulating occurrence of the event in a predetermined area, with an occurrence position of the simulated event information being a position in the predetermined area based on the position included in the past event information and the supplementary information regarding the position.

### Supplementary Note 2

A non-transitory storage medium storing a program executable by a computer for execution of information generation processing,
in which the information generation processing includes:
acquiring past event information including information on a position where a predetermined event occurred and supplementary information regarding the position; and
generating simulated event information obtained by simulating occurrence of the event in a predetermined area, with an occurrence position of the simulated event information being a position in the predetermined area based on the position included in the past event information and the supplementary information regarding the position.

### REFERENCE SIGNS LIST

1 Information generation system
10 Information generation device
11 CPU
12 ROM
13 RAM
14 Storage
17 Communication I/F
19 Bus
101 Acquisition unit
102 Generation unit
120 Event database

1. An information generation device comprising a processor configured to execute operations comprising:
acquiring past event information, wherein the past event information includes information of a position where a predetermined event occurred and supplementary information regarding the position; and
generating simulated event information, wherein the simulated event information is obtained by simulating occurrence of an event in a predetermined area, with an occurrence position of the simulated event information being a position in the predetermined area based on the position included in the past event information and the supplementary information regarding the position.

2. The information generation device according to claim 1, wherein the supplementary information indicates a type of a facility in which the event occurred.

3. The information generation device according to claim 2, wherein the generating further comprises:
setting, as the occurrence position, a position obtained by adding noise to the position included in the past event information in a case where the type of the facility indicated by the supplementary information regarding a position selected from positions included in the past event information is a first type, and
setting, as the occurrence position, the position included in the past event information in a case where the type of the facility indicated by the supplementary information regarding the selected position is a second type that is lower than facilities of the first type in probability that the event occurs in a vicinity of the selected position.

4. The information generation device according to claim 3, wherein the generating further comprises setting, as the occurrence position, a position represented by latitude and longitude obtained by adding a predetermined value to at least one of latitude or longitude of the position included in the past event information in a case where noise is added to the position included in the past event information.

5. The information generation device according to claim 1, wherein the generating further comprises generating pieces of the simulated event information, a number of the pieces being based on an occurrence probability of the event calculated from the past event information.

6. An information generation system comprising a processor configured to execute operations comprising:
acquiring past event information, wherein the past event information includes information of a position where a predetermined event occurred and supplementary information regarding the position; and
generating simulated event information, wherein the simulated event information is obtained by simulating occurrence of an event in a predetermined area, with an occurrence position of the simulated event information being a position in the predetermined area based on the position included in the past event information and the supplementary information regarding the position.

7. A computer implemented method for generating information, comprising:
acquiring past event information, wherein the past event information includes information of a position where a predetermined event occurred and supplementary information regarding the position; and
generating simulated event information, wherein the simulated event information is obtained by simulating occurrence of an event in a predetermined area, with an occurrence position of the simulated event information being a position in the predetermined area based on the position included in the past event information and the supplementary information regarding the position.

8. (canceled)

9. The information generation device according to claim 2, wherein the generating further comprises generating pieces of the simulated event information, a number of the pieces being based on an occurrence probability of the event calculated from the past event information.

10. The information generation system according to claim 6, wherein the supplementary information indicates a type of a facility in which the event occurred.

11. The information generation system according to claim 10, wherein the generating further comprises:
setting, as the occurrence position, a position obtained by adding noise to the position included in the past event information in a case where the type of the facility indicated by the supplementary information regarding a position selected from positions included in the past event information is a first type, and
setting, as the occurrence position, the position included in the past event information in a case where the type of the facility indicated by the supplementary information regarding the selected position is a second type that is lower than facilities of the first type in probability that the event occurs in a vicinity of the selected position.

12. The information generation system according to claim 11, wherein the generating further comprises setting, as the occurrence position, a position represented by latitude and longitude obtained by adding a predetermined value to at least one of latitude or longitude of the position included in the past event information in a case where noise is added to the position included in the past event information.

13. The information generation system according to claim 6, wherein the generating further comprises generating pieces of the simulated event information, a number of the pieces being based on an occurrence probability of the event calculated from the past event information.

14. The information generation system according to claim 10, wherein the generating further comprises generating pieces of the simulated event information, a number of the pieces being based on an occurrence probability of the event calculated from the past event information.

15. The computer implemented method according to claim 7, wherein the supplementary information indicates a type of a facility in which the event occurred.

16. The computer implemented method according to claim 15, wherein the generating further comprises:
setting, as the occurrence position, a position obtained by adding noise to the position included in the past event information in a case where the type of the facility indicated by the supplementary information regarding a position selected from positions included in the past event information is a first type, and
setting, as the occurrence position, the position included in the past event information in a case where the type of the facility indicated by the supplementary information regarding the selected position is a second type that is lower than facilities of the first type in probability that the event occurs in a vicinity of the selected position.

17. The computer implemented method according to claim 16, wherein the generating further comprises setting, as the occurrence position, a position represented by latitude and longitude obtained by adding a predetermined value to at least one of latitude or longitude of the position included in the past event information in a case where noise is added to the position included in the past event information.

18. The computer implemented method according to claim 7, wherein the generating further comprises generating pieces of the simulated event information, a number of the pieces being based on an occurrence probability of the event calculated from the past event information.
